(19) United States
(12) Patent Application Publication
(10) Pub. No.: US 2025/0167071 A1
(43) Pub. Date: May 22, 2025

(54) CERAMIC SUBSTRATE UNIT AND MANUFACTURING METHOD THEREFOR

(71) Applicant: AMOGREENTECH CO., LTD., Gimpo-si, Gyeonggi-do (KR)

(72) Inventor: Jihyung LEE, Gimpo-si (KR)

(73) Assignee: AMOGREENTECH CO., LTD., Gimpo-si, Gyeonggi-do (KR)

(21) Appl. No.: 18/841,321

(22) PCT Filed: Feb. 14, 2023
(86) PCT No.: PCT/KR2023/002093

§ 371 Date: Aug. 23, 2024

(30) Foreign Application Priority Data
Feb. 24, 2022 (KR) 10-2022-0024253

(51) Int. Cl. H01L 23/373; H01L 21/48; H01L 23/15

(52) U.S. Cl. CPC H01L 23/3735; H01L 21/4807; H01L 21/4882; H01L 23/15

(57) ABSTRACT

The present disclosure relates to a ceramic substrate unit and a manufacturing method therefor, which can suppress warpage due to a difference between the volumes of upper and lower metal layers in a ceramic substrate by calculating the volume of the upper metal layer and forming a plurality of grooves in the lower metal layer to have a predetermined volume corresponding to the volume of an upper electrode.

### TECHNICAL FIELD

The present disclosure relates to a ceramic substrate unit and a method of manufacturing the same, and more specifically, to a ceramic substrate unit capable of enhancing a heat dissipation effect by suppressing warpage of a ceramic substrate and improving bonding reliability, and a method of manufacturing the same.

### BACKGROUND ART

In general, a heat sink in a ceramic substrate unit applied to a power module is formed in a quadrangular plate shape and is made of an aluminum or copper material. The heat sink may be bonded to a lower surface of the ceramic substrate and soldered to the lower surface of the ceramic substrate to facilitate heat dissipation. Since the heat sink is mainly made of a material with a coefficient of thermal expansion of 17.8 ppm/mK or more, there may occur warpage due to a difference in thermal expansion during a bonding process with the ceramic substrate. In addition, the solder paste may melt at a high temperature, causing warpage, defect, etc. of the heat sink.

As a solution to this, the ceramic substrate and the heat sink are bonded at a temperature of 250° C. or lower using AlSiC or a similar material. According to the conventional method of bonding the heat sink and the ceramic substrate, the heat sink is soldered to the ceramic substrate using a solder preform. In this case, the solder preform uses SAC305 made of a composition containing Sn, Ag, and Cu, and a soldering temperature ranges from 230 to 350° C.

However, in the conventional ceramic substrate unit, process cost is increased due to processes of solder paste, solder preform, and vacuum bonding equipment used for bonding, and warpage occurs at a high temperature due to a volume difference between upper and lower metal layers of the ceramic substrate and a coefficient of thermal expansion, resulting in bonding reliability and yield problems.

The matters described above in the background art are intended to help understanding of the background of the disclosure and may include matters not related to the known related art.

### SUMMARY OF INVENTION

### Technical Problem

The present disclosure has been made in efforts to solve the problems and is directed to providing a ceramic substrate unit and a method of manufacturing the same, in which can prevent the occurrence of warpage at a high temperature due to a volume difference between an upper metal layer and a lower metal layer of a ceramic substrate, enable high reliability bonding, and effectively dissipate heat generated from a semiconductor chip.

### Solution to Problem

A ceramic substrate unit according to an embodiment of the present disclosure for achieving the object may include a ceramic substrate, and a heat sink bonded to the ceramic substrate, wherein the ceramic substrate may include an upper metal layer formed on an upper surface of a ceramic base and formed so that a semiconductor chip is mounted thereon, and a lower metal layer formed on a lower surface of the ceramic base and having the heat sink bonded to a lower surface thereof, and the lower metal layer may have a plurality of grooves formed in an upper surface facing the lower surface of the ceramic base, and the plurality of grooves may form an air gap between the lower surface of the ceramic base and the upper surface of the lower metal layer.

Here, a volume ratio obtained by dividing a total volume of the upper metal layer by a total volume of the lower metal layer may range from 0.9 to 1.1.

The plurality of grooves may be formed by etching a portion of the upper surface of the lower metal layer in a thickness direction. In addition, the plurality of grooves may be disposed in an a×b matrix (a and b are each a natural number of 2 or more).

The lower surface of the lower metal layer may be provided as a flat surface and bonded to the heat sink without the air gap.

The ceramic substrate unit may include a brazing filler disposed between the upper surface of the ceramic base and a lower surface of the upper metal layer and between the lower surface of the ceramic base and the upper surface of the lower metal layer and bonding the upper metal layer and the lower metal layer to the ceramic base. Here, the brazing filler may be disposed in an area of the upper surface of the lower metal layer excluding the plurality of grooves.

A method of manufacturing a ceramic substrate unit may include preparing a ceramic base, preparing an upper metal layer formed so that a semiconductor chip is mounted, preparing a lower metal layer having a plurality of grooves formed in an upper surface thereof, bonding the upper metal layer to an upper surface of the ceramic base and bonding the lower metal layer to a lower surface of the ceramic base, and bonding a heat sink to a lower surface of the lower metal layer, wherein the plurality of grooves may form an air gap between the lower surface of the ceramic base and an upper surface of the lower metal layer.

The preparing of the lower metal layer may include forming the plurality of grooves so that a volume ratio obtained by dividing a total volume of the upper metal layer by a total volume of the lower metal layer ranges from 0.9 to 1.1.

The preparing of the lower metal layer may include forming the plurality of grooves by etching a portion of the upper surface of the lower metal layer in a thickness direction.

In the preparing of the lower metal layer, the plurality of grooves may be disposed in an a×b matrix (a and b are each a natural number of 2 or more).

The bonding of the upper metal layer to the upper surface of the ceramic base and bonding of the lower metal layer to the lower surface of the ceramic base may include arranging a brazing filler between the upper surface of the ceramic base and a lower surface of the upper metal layer and between the lower surface of the ceramic base and the upper surface of the lower metal layer, and melting and brazing the brazing filler.

The arranging of the brazing filler may include arranging the brazing filler having a thickness of 5 μm or more and 100 μm or less in any one method of paste application, foil attachment, and a P-filler.

### Advantageous Effects of Invention

According to the present disclosure, since the plurality of grooves are formed by etching the portion of the upper surface of the lower metal layer in the thickness direction, the volume ratio of the upper metal layer and the lower metal layer may be controlled to be within the range of 0.9 to 1.1 without changing the total thickness of the lower metal layer, thereby suppressing the warpage caused by the volume difference between the upper metal layer and the lower metal layer.

In addition, according to the present disclosure, it is possible to suppress the warpage phenomenon caused by the volume difference between the upper metal layer and the lower metal layer, thereby enhancing bonding reliability, maximizing the heat dissipation effect, and reducing the defect rate to increase productivity.

In addition, according to the present disclosure, even when high-temperature heat is generated from the semiconductor chip, the heat can be quickly cooled by the heat sink, and thus the semiconductor chip can be maintained at the constant temperature without deterioration.

### BRIEF DESCRIPTION OF DRAWINGS

FIG. 1 is a perspective view showing a ceramic substrate unit according to one embodiment of the present disclosure.

FIG. 2 is a plan view showing a ceramic substrate of the ceramic substrate unit according to one embodiment of the present disclosure from which an upper metal layer and a ceramic base have been omitted.

FIG. 3 is a cross-sectional view of the ceramic substrate along line A-A′ in FIG. 2.

FIG. 4 is a plan view showing a ceramic substrate of a ceramic substrate unit according to another embodiment of the present disclosure from which an upper metal layer and a ceramic base have been omitted.

FIG. 5 is a cross-sectional view of the ceramic substrate along line A-A′ in FIG. 4.

FIG. 6 is a flowchart showing a method of manufacturing the ceramic substrate unit according to one embodiment of the present disclosure.

### DESCRIPTION OF EMBODIMENTS

Hereinafter, exemplary embodiments according to the present disclosure will be described in detail with reference to the accompanying drawings.

The embodiments are provided to more completely describe the present disclosure to those skilled in the art, and the following embodiments may be modified in various different forms, and the scope of the present disclosure is limited to the following embodiments. Rather, the embodiments are provided to make the disclosure more faithful and complete and fully convey the spirit of the present disclosure.

Terms used herein are intended to describe specific embodiments and are not intended to limit the present disclosure. In addition, in the present specification, singular forms may include plural forms unless the context clearly indicates otherwise.

In the description of the embodiment, when each layer (film), area, pattern, or structure is described as being formed “on” or “under” a substrate, each layer (film), area, pad, or patterns, “on” and “under” include both cases of being formed “directly” or “indirectly with other elements interposed therebetween.” In addition, in principle, the reference for “above” or “under” each layer are based on the drawing.

The drawings are only intended to help understanding of the spirit of the present disclosure and should not be construed as limiting the scope of the present disclosure by the drawings. In addition, in the drawings, a relative thickness and length, or a relative size may be exaggerated for convenience and clarity of description.

Hereinafter, embodiments of the present disclosure will be described in detail with reference to the accompanying drawings.

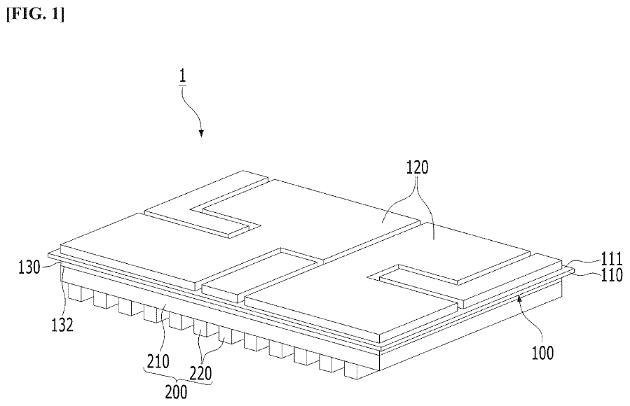

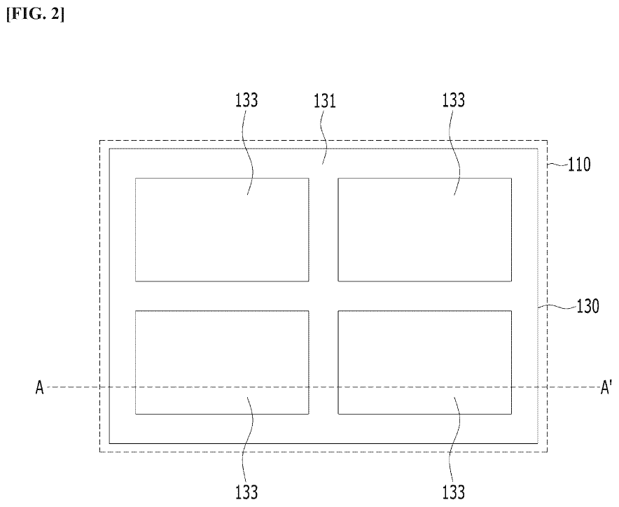

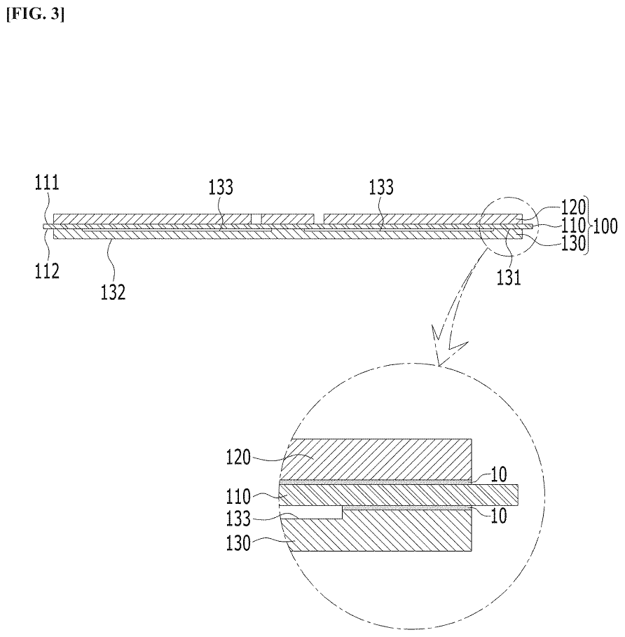

FIG. 1 is a perspective view showing a ceramic substrate unit according to one embodiment of the present disclosure, FIG. 2 is a plan view showing a ceramic substrate of the ceramic substrate unit according to one embodiment of the present disclosure from which an upper metal layer and a ceramic base have been omitted, and FIG. 3 is a cross-sectional view of the ceramic substrate along line A-A′ in FIG. 2.

As shown in FIGS. 1 to 3, a ceramic substrate unit 1 according to an embodiment of the present disclosure may include a ceramic substrate 100 and a heat sink 200 bonded to the ceramic substrate 100.

The ceramic substrate 100 may be an active metal brazing (AMB) substrate including a ceramic base 110 and upper and lower metal layers 120 and 130 formed on upper and lower surfaces of the ceramic base 110. In an embodiment, the AMB substrate will be described as an example, but the DBC substrate, the TPC substrate, or a direct brazed aluminum (DBA) substrate may be applied. The AMB substrate is most suitable in terms of durability and heat dissipation efficiency of heat generated from a semiconductor chip.

The ceramic base 110 of the ceramic substrate 100 may be, for example, any one of alumina (Al₂O₃), AIN, zirconia-reinforced alumina (ZTA), SiN, and Si₃N₄.

The upper metal layer 120 may be formed as an electrode pattern on an upper surface 111 of the ceramic base 110. For example, the upper metal layer 120 may be provided in the form of a metal foil, brazing-bonded to the upper surface 111 of the ceramic base 110, and then formed as an electrode pattern on which a semiconductor chip (not shown) is mounted by etching. In addition, the upper metal layer 120 may be formed to be thicker by plating, bonding, etc. For example, the upper metal layer 120 may be made of one of Cu, a Cu alloy (CuMo, etc.), OFC, EPT Cu, and Al. OFC is anoxic copper.

The lower metal layer 130 may be formed on a lower surface 112 of the ceramic base 110 and may have an upper surface 131 bonded to the lower surface 112 of the ceramic base 110 and a lower surface 132 bonded to the heat sink 200. The lower metal layer 130 may be, for example, made of one of Cu, a Cu alloy (CuMo, etc.), OFC, EPT Cu, and Al.

The lower surface 132 of the lower metal layer 130 may be formed as a flat surface to increase heat dissipation efficiency by increasing a bonding area with the heat sink 200. That is, the lower surface 132 of the lower metal layer 130 may be bonded to the heat sink 200 without an air gap.

Referring to FIGS. 2 and 3, the upper surface 131 of the lower metal layer 130 is a surface facing the lower surface 112 of the ceramic base 110, and a plurality of grooves 133 may be formed in the upper surface 131. The lower metal layer 130 may be disposed in a matrix form so that the plurality of grooves 133 are spaced by a predetermined distance from each other in the upper surface 131. The plurality of grooves 133 may be disposed in a matrix form uniformly over the entire area or set area of the upper surface 131. In addition, the plurality of grooves 133 may be disposed in an a×b matrix (a and b are each a natural number of 2 or more). For example, as shown in FIG. 2, a total of four grooves in which the plurality of grooves 133 are disposed in a 2×2 matrix may be provided.

The plurality of grooves 133 may be formed by etching a portion of an upper surface of the lower metal layer 130 in a thickness direction. Alternatively, the plurality of grooves 133 may be formed by mechanically processing a portion of the upper surface of the lower metal layer 130. The plurality of grooves 133 may form an air gap between the lower surface 112 of the ceramic base 110 and the upper surface 131 of the lower metal layer 130 and suppress the warping phenomenon caused by a volume difference between the upper metal layer 120 and the lower metal layer 130 by adjusting a volume of the lower metal layer 130. For example, when a thickness of each of the upper and lower metal layers 120 and 130 in the ceramic substrate 100 is 0.6 mm and a thickness at which the plurality of grooves 133 are etched is 0.15 mm, a volume ratio obtained by dividing the total volume of the upper metal layer 120 by the total volume of the lower metal layer 130 in the form of a flat plate without grooves is about 0.9, and an average warpage value in the case of negative warpage at 200° C. or higher, that is, in the case of the phenomenon that the lower metal layer 130 has a larger volume and thus warps upward, is a very small value of about 0.1 mm.

On the other hand, when the upper surface 131 of the lower metal layer 130 is formed as a flat surface without the plurality of grooves 133 like the lower surface 132, the volume difference is large compared to the total volume of the upper metal layer 120 formed as an electrode pattern, and thus the ceramic substrate 100 warps in a high-temperature environment. According to empirical data, a volume ratio obtained by dividing the total volume of the upper metal layer 120 formed as an electrode pattern by the total volume of the lower metal layer 130 in the form of a flat plate without grooves is about 0.76, and an average warpage value in the case of negative warpage at 200° C. or higher is about 0.358 mm, which shows a significant change. This warpage accounts for a relatively large proportion of the total production volume, resulting in a problem of continuous production loss.

In addition, the upper metal layer 120 and the lower metal layer 130 are made of a material such as Cu and Al with excellent thermal conductivity, and since these materials have a coefficient of thermal expansion of 17.8 ppm/mK or more, there is a problem that warpage occurs significantly at a high temperature of 200° C. or higher. As described above, the ceramic substrate 100 warps depending on the sizes and shapes of the upper and lower metal layers 120 and 130, the coefficient of thermal expansion, etc.

Since the upper metal layer 120 of the ceramic substrate 100 is formed as a circuit pattern and is configured to mount a semiconductor chip, its shape, thickness, length, etc. are often designed to be fixed. Therefore, in the ceramic substrate unit 1 according to the embodiment of the present disclosure, by calculating the volume of the upper metal layer 120 bonded to the ceramic base 110 of the ceramic substrate 100 and forming the plurality of grooves 133 in the upper surface of the lower metal layer 130 to have a predetermined volume corresponding to the volume of the upper metal layer 120, it is possible to suppress the warpage phenomenon that occurs at a high temperature.

Specifically, the volume ratio obtained by dividing the total volume of the upper metal layer 120 by the total volume of the lower metal layer 130 is preferably designed to be within a range of 0.9 to 1.1 and to minimize warpage, the volume ratio is more preferably designed to be close to 1.0. Here, the total volume may be calculated by multiplying a total area by a thickness.

The thicknesses of the upper metal layer 120 and the lower metal layer 130 may range from 0.3 mm to 20 mm. Since the ceramic substrate unit 1 according to the present disclosure may be applied to the power module, the thicknesses of the upper metal layer 120 and the lower metal layer 130 may be designed in consideration of a thickness of the power module. The power module is provided with a semiconductor chip, the power module is sealed with an epoxy-based molding resin to protect the semiconductor chip from an external environment, and in this case, a molding mold is used, and thus the thicknesses of the upper metal layer 120 and the lower metal layer 130 may be designed in consideration of a height of the molding mold. As described above, since the thicknesses of the upper metal layer 120 and the lower metal layer 130 are designed in consideration of a product, process conditions, heat dissipation, etc., it is difficult to change the same later.

The ceramic substrate unit 1 according to the present disclosure can solve a problem that it is difficult to suppress warpage due to the limitation in changing the thicknesses of the upper metal layer 120 and the lower metal layer 130. That is, in the ceramic substrate unit 1 according to the present disclosure, since the plurality of grooves 133 are formed by etching the portion of the upper surface of the lower metal layer 130 in the thickness direction, the volume of the lower metal layer 130 can be reduced without changing the total thickness of the lower metal layer 130, and thus the volume ratio of the upper metal layer 120 and the lower metal layer 130 may be adjusted to be within the range of 0.9 to 1.1. As described above, according to the present disclosure, it is possible to suppress the warpage phenomenon caused by the volume difference between the upper metal layer 120 and the lower metal layer 130 by controlling the sizes (volumes) of the plurality of grooves 133 formed in the lower metal layer 130.

Meanwhile, the ceramic substrate unit 1 according to the present disclosure may include a brazing filler 10 that is disposed between the upper surface 111 of the ceramic base 110 and the lower surface 112 of the upper metal layer 120 and between the lower surface 112 of the ceramic base 110 and the upper surface 131 of the lower metal layer 130 and bonds the upper metal layer 120 and the lower metal layer 130 to the ceramic base 110. Here, as shown in FIG. 3, the brazing filler 10 may be disposed in an area of the upper surface of the lower metal layer 130 excluding the plurality of grooves 133. Therefore, the lower metal layer 130 may be bonded to the ceramic base 110 while maintaining a state in which the plurality of grooves 133 are air gaps.

The brazing filler 10 may be made of a material including at least one of Ag, Cu, AgCu, and AgCuTi. Here, Ag and Cu may serve to increase bonding strength by having high thermal conductivity and at the same time, increase heat dissipation efficiency by facilitating heat transfer. In addition, Ti can easily allow Ag and Cu to be attached to the bonding surface by having good wettability.

Meanwhile, the heat sink 200 may be used to dissipate heat generated from the semiconductor chip mounted on the upper metal layer 120 and made of a material capable of increasing heat dissipation efficiency. As an example, the heat sink 200 may be made of at least one of Cu, Al, AlSiC, CuMo, CuW, Cu/CuMo/Cu, Cu/Mo/Cu, and Cu/W/Cu, or a composite material thereof. Here, the materials of Cu, Al, AlSiC, CuMo, CuW, Cu/CuMo/Cu, Cu/Mo/Cu, and Cu/W/Cu may have excellent thermal conductivity, and the materials of AlSiC, CuMo, CuW, Cu/CuMo/Cu, Cu/Mo/Cu, and Cu/W/Cu may have low thermal expansion coefficients, thereby minimizing the occurrence of warpage when bonded to the ceramic substrate 100.

The heat sink 200 may be operated by any one of an air-cooled method or a water-cooled method. Here, for the air-cooled method, air may be supplied as refrigerant, and for the water-cooled method, cooling water may be supplied by being circulated as refrigerant by a pumping force. In the present embodiment, the slit-type heat sink 200 in which a plurality of bar-shaped protrusions 220 are horizontally disposed at intervals on a lower surface of a body 210 is shown, but the present disclosure is not limited thereto, and as the heat sink 200, various heat sinks such as a micro channel, pin fin, micro jet, and slit types may be bonded.

Although not shown, the heat sink 200 may be bonded to the lower metal layer 130 of the ceramic substrate 100 via a bonding layer (not shown). In this case, the bonding layer may be a brazing bonding layer or Ag sintering bonding layer made of a material including at least one of Ag, Cu, AgCu, and AgCuTi. When the bonding layer is a brazing bonding layer, the brazing bonding layer may be disposed between the lower metal layer 130 of the ceramic substrate 100 and the heat sink 200 and may integrally bond the ceramic substrate 100 and the heat sink 200 at a brazing temperature. The brazing temperature may be 450° C. or higher. Ag, AgCu, and AgCuTi may serve to increase bonding strength due to high thermal conductivity and at the same time, facilitate heat transfer between the ceramic substrate 100 and the heat sink 200, thereby increasing heat dissipation efficiency.

When the bonding layer is an Ag sintering bonding layer, the bonding layer may be made of a material including an Ag sintered body. For example, when the bonding layer is an Ag sintered body film, the Ag sintered body film may be disposed between the lower metal layer 130 of the ceramic substrate 100 and the heat sink 200, and in this state, by applying a pressure to the above assembly and hardening the same, the ceramic substrate 100 and the heat sink 200 may be integrally bonded. As described above, the ceramic substrate 100 and the heat sink 200 are airtightly bonded by a bonding method such as brazing bonding or Ag sintering bonding, thereby having high bonding strength and excellent high-temperature reliability.

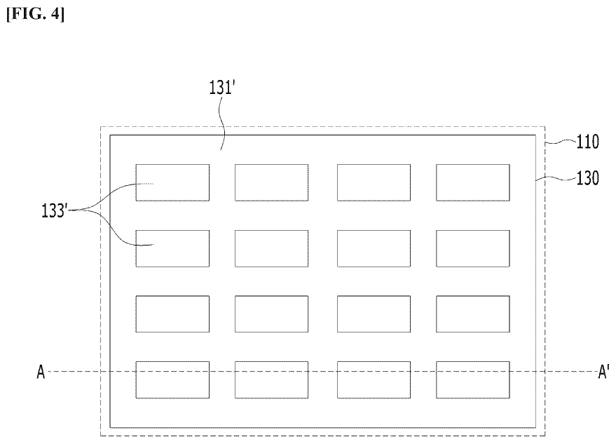

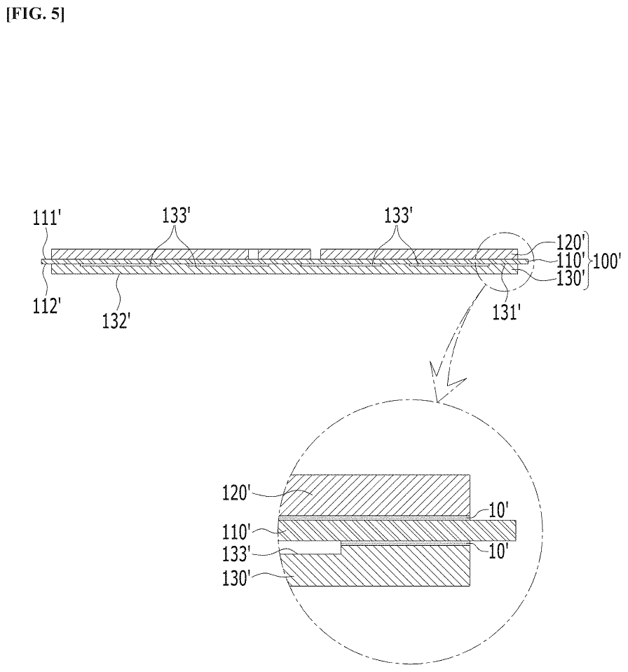

FIG. 4 is a plan view showing a ceramic substrate of a ceramic substrate unit according to another embodiment of the present disclosure from which an upper metal layer and a ceramic base have been omitted, and FIG. 5 is a cross-sectional view of the ceramic substrate along line A-A′ in FIG. 4.

As shown in FIGS. 4 and 5, in a ceramic substrate unit 1′ according to another embodiment of the present disclosure, a total of 16 grooves in which a plurality of grooves 133′ are disposed in a 4×4 matrix may be provided in an upper surface of a lower metal layer 130′ of a ceramic substrate 100′. As described above, the lower metal layer 130′ may be disposed in a matrix form so that the plurality of grooves 133′ are spaced by a predetermined distance from each other in an upper surface 131′. The plurality of grooves 133′ may be disposed in a matrix form uniformly over the entire area or set area of the upper surface 131′. In addition, the plurality of grooves 133′ may be disposed in an a×b matrix (a and b are each a natural number of 2 or more). In the present embodiment, an example in which a total of 16 grooves in which the plurality of quadrangular grooves 133′ are disposed in a 4×4 matrix are provided is shown, but the numbers and shapes of the plurality of grooves 133′ are not limited thereto.

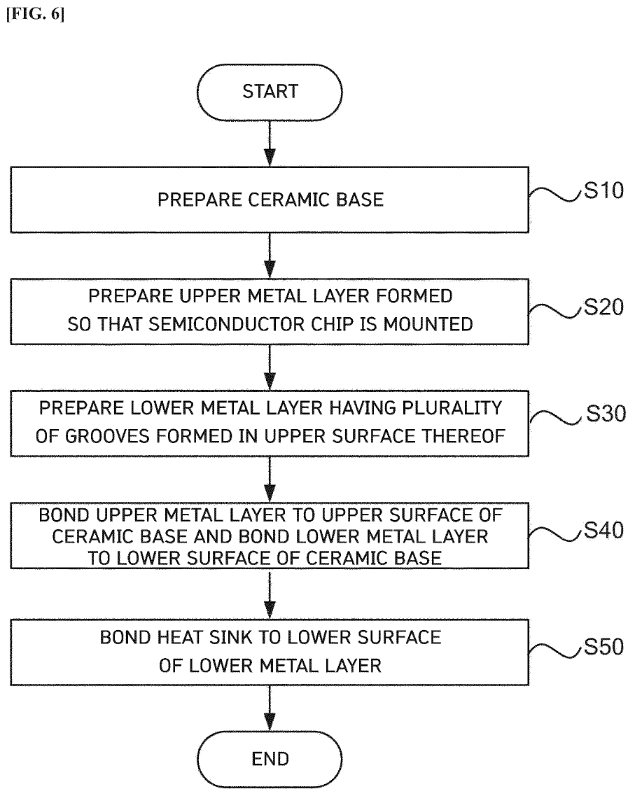

FIG. 6 is a flowchart showing a method of manufacturing the ceramic substrate unit according to one embodiment of the present disclosure.

The method of manufacturing the ceramic substrate unit according to one embodiment of the present disclosure may include preparing the ceramic base 110 (S10), preparing the upper metal layer 120 configured so that a semiconductor chip is mounted (S20), preparing the lower metal layer 130 in which the plurality of grooves 133 are formed in the upper surface thereof (S30), bonding the upper metal layer 120 to the upper surface 111 of the ceramic base 110 and bonding the lower metal layer 130 to the lower surface 112 of the ceramic base 110 (S40), and bonding the heat sink 200 to the lower surface of the lower metal layer 130 (S50). Here, each operation may be performed sequentially or performed in a reversed order, and performed substantially at the same time.

In the preparing of the ceramic base 110 (S10), the ceramic base 110 may be any one of alumina (Al₂O₃), AlN, SiN, Si₃N₄, and zirconia toughened alumina (ZTA), but is not limited thereto.

In the preparing of the upper metal layer 120 (S20), the upper metal layer 120 may be provided in a circuit pattern shape. In addition, the upper metal layer 120 may be provided in the form of a metal foil, brazing-bonded to the upper surface of the ceramic base 110, and then formed as an electrode pattern on which a semiconductor chip is mounted by etching. For example, the upper metal layer 120 may be made of one of Cu, a Cu alloy (CuMo, etc.), OFC, EPT Cu, and Al.

In the preparing of the lower metal layer 130 (S30), the lower surface 132 of the lower metal layer 130 may be formed as a flat surface to increase heat dissipation efficiency by increasing the bonding area with the heat sink 200. The lower surface 132 of the lower metal layer 130 may be bonded to the heat sink 200 without an air gap. On the other hand, the upper surface 131 of the lower metal layer 130 may be formed with the plurality of grooves 133. The plurality of grooves 133 may form an air gap between the lower surface 112 of the ceramic base 110 and the upper surface 131 of the lower metal layer 130.

The preparing of the lower metal layer 130 (S30) may include forming the plurality of grooves 133 so that the volume ratio obtained by dividing the total volume of the upper metal layer 120 by the total volume of the lower metal layer 130 is within a range of 0.9 to 1.1. Here, the plurality of grooves 133 may be formed by etching a portion of the upper surface of the lower metal layer 130 in the thickness direction. Alternatively, the plurality of grooves 133 may be formed by mechanically processing the portion of the upper surface of the lower metal layer 130.

In the preparing of the lower metal layer 130 (S30), the plurality of grooves 133 may be disposed in an a×b matrix (a and b are each a natural number of 2 or more). For example, a total of 4 grooves in which the plurality of grooves 133 are disposed in a 2×2 matrix may be provided as shown in FIG. 2, and a total of 16 grooves in which the plurality of grooves 133 are disposed in a 4×4 matrix may be provided as shown in FIG. 4.

As described above, in the method of manufacturing the ceramic substrate unit according to the present disclosure, since the plurality of grooves 133 are formed by etching the portion of the upper surface of the lower metal layer 130 in the thickness direction, the volume of the lower metal layer 130 can be adjusted without changing the total thickness of the lower metal layer 130, and thus the volume ratio of the upper metal layer 120 and the lower metal layer 130 may be adjusted to be within the range of 0.9 to 1.1. As described above, the volume ratio of the upper metal layer 120 and the lower metal layer 130 may be controlled to be within a specific range, thereby suppressing the warpage phenomenon at a high temperature.

The bonding of the upper metal layer 120 to the upper surface 111 of the ceramic base 110 and bonding of the lower metal layer 130 to the lower surface 112 of the ceramic base 110 (S40) may include arranging the brazing filler 10 between the upper surface 111 of the ceramic base 110 and the lower surface of the upper metal layer 120 and between the lower surface 112 of the ceramic base 110 and the upper surface 131 of the lower metal layer 130 (S41), and melting and brazing the brazing filler 10 (S42).

In the arranging of the brazing filler 10 (S41), the brazing filler 10 may be disposed between the upper surface 111 of the ceramic base 110 and the lower surface of the upper metal layer 120 and between the lower surface 112 of the ceramic base 110 and the upper surface 131 of the lower metal layer 130 and as shown in FIG. 3, disposed in an area of the upper surface of the lower metal layer 130 excluding the plurality of grooves 133. Therefore, the lower metal layer 130 may be bonded to the ceramic base 110 while maintaining a state in which the plurality of grooves 133 are air gaps.

The arranging of the brazing filler 10 (S41) may include arranging the brazing filler 10 having a thickness of 5 μm or more and 100 μm or less in any one method of paste application, foil attachment, and P-filler. The brazing filler 10 may be made of a material including at least one of Ag, Cu, AgCu, and AgCuTi. The brazing (S42) may be performed at 450° C. or higher, preferably, in a range of 780 to 900° C., and an upper weight or pressure may be applied to increase bonding strength during brazing. Since the brazing bonding does not require vacuum bonding equipment, etc., as with the use of solder preform, the process can be simplified, and by applying the upper weight or pressure, pore defects are prevented and the bonding strength is increased, thereby achieving high bonding reliability.

The bonding of the heat sink 200 (S50) may include bonding the heat sink 200 to the lower metal layer 130 via the bonding layer (not shown) formed between the lower metal layer 130 of the ceramic substrate 100 and the heat sink 200, and the bonding layer may be made of a material including at least one of Ag, Cu, AgCu, and AgCuTi or a material including an Ag sintered body. When the bonding layer is a brazing bonding layer made of the material including at least one of Ag, Cu, AgCu, and AgCuTi, the brazing bonding layer may be disposed between the lower metal layer 130 and the heat sink 200 and may integrally bond the ceramic substrate 100 and the heat sink 200 at a brazing temperature. The bonding layer may be formed by any one method of plating, paste application, and foil attachment and may have a thickness of about 5 to 100 μm. The brazing bonding may be performed at 450° C. or higher, preferably, in a range of 780 to 900° C., and pressing by a jig may be performed during brazing to increase bonding strength.

When the bonding layer is an Ag sintering bonding layer, the bonding layer may be made of a material including an Ag sintered body. For example, when the bonding layer is an Ag sintered body film, the Ag sintered body film may be disposed between the lower metal layer 130 and the heat sink 200, and in this state, by applying a pressure to the above assembly and hardening the same, the ceramic substrate 100 and the heat sink 200 may be integrally bonded.

The above-described ceramic substrate unit according to the present disclosure can secure both multiple and large amount of connections of the semiconductor chip and the heat dissipation effect and further improve the performance of the power modules.

The above-described ceramic substrate unit according to the present disclosure can be applied to various module parts used for high power in addition to the power module.

The above description is merely the exemplary description of the technical spirit of the present disclosure, and those skilled in the art to which the present disclosure pertains will be able to variously modify and change the present disclosure without departing from the essential characteristics of the present disclosure. Therefore, the embodiments disclosed in the present disclosure are not intended to limit the technical spirit of the present disclosure, but intended to describe the same, and the scope of the technical spirit of the present disclosure is not limited by these embodiments. The scope of the present disclosure should be construed by the appended claims, and all technical spirits within the equivalent scope should be construed as being included in the scope of the present disclosure.

1. A ceramic substrate unit comprising:
a ceramic substrate; and
a heat sink bonded to the ceramic substrate,
wherein the ceramic substrate includes:
an upper metal layer formed on an upper surface of a ceramic base and formed so that a semiconductor chip is mounted thereon; and
a lower metal layer formed on a lower surface of the ceramic base and having the heat sink bonded to a lower surface thereof, and
the lower metal layer has a plurality of grooves formed in an upper surface facing the lower surface of the ceramic base, and the plurality of grooves form an air gap between the lower surface of the ceramic base and the upper surface of the lower metal layer.

2. The ceramic substrate unit of claim 1, wherein a volume ratio obtained by dividing a total volume of the upper metal layer by a total volume of the lower metal layer ranges from 0.9 to 1.1.

3. The ceramic substrate unit of claim 1, wherein the plurality of grooves are formed by etching a portion of the upper surface of the lower metal layer in a thickness direction.

4. The ceramic substrate unit of claim 1, wherein the plurality of grooves are disposed in an a×b matrix (a and b are each a natural number of 2 or more).

5. The ceramic substrate unit of claim 1, wherein the lower surface of the lower metal layer is provided as a flat surface and bonded to the heat sink without the air gap.

6. The ceramic substrate unit of claim 1, comprising a brazing filler disposed between the upper surface of the ceramic base and a lower surface of the upper metal layer and between the lower surface of the ceramic base and the upper surface of the lower metal layer and bonding the upper metal layer and the lower metal layer to the ceramic base.

7. The ceramic substrate unit of claim 6, wherein the brazing filler is disposed in an area of the upper surface of the lower metal layer excluding the plurality of grooves.

8. A method of manufacturing a ceramic substrate unit, the method comprising:
preparing a ceramic base;
preparing an upper metal layer formed so that a semiconductor chip is mounted;
preparing a lower metal layer having a plurality of grooves formed in an upper surface thereof;
bonding the upper metal layer to an upper surface of the ceramic base and bonding the lower metal layer to a lower surface of the ceramic base; and
bonding a heat sink to a lower surface of the lower metal layer,
wherein the plurality of grooves form an air gap between the lower surface of the ceramic base and an upper surface of the lower metal layer.

9. The method of claim 8, wherein the preparing of the lower metal layer includes forming the plurality of grooves so that a volume ratio obtained by dividing a total volume of the upper metal layer by a total volume of the lower metal layer ranges from 0.9 to 1.1.

10. The method of claim 8, wherein the preparing of the lower metal layer includes forming the plurality of grooves by etching a portion of the upper surface of the lower metal layer in a thickness direction.

11. The method of claim 8, wherein in the preparing of the lower metal layer, the plurality of grooves are disposed in an a×b matrix (a and b are each a natural number of 2 or more).

12. The method of claim 8, wherein the bonding of the upper metal layer to the upper surface of the ceramic base and bonding of the lower metal layer to the lower surface of the ceramic base includes:
arranging a brazing filler between the upper surface of the ceramic base and a lower surface of the upper metal layer and between the lower surface of the ceramic base and the upper surface of the lower metal layer; and
melting and brazing the brazing filler.

13. The method of claim 12, wherein the arranging of the brazing filler includes arranging the brazing filler having a thickness of 5 μm or more and 100 μm or less in any one method of paste application, foil attachment, and a P-filler.
